(19) United States
(12) Patent Application Publication
(10) Pub. No.: US 2013/0095655 A1
(43) Pub. Date: Apr. 18, 2013

(54) Methods Of Forming Circuit Structures Within Openings And Methods Of Forming Conductive Lines Across At Least A Portion Of A Substrate

(71) Applicants: Sony Varghese, Boise, ID (US); Sanh D. Tang, Boise, ID (US)

(72) Inventors: Sony Varghese, Boise, ID (US); Sanh D. Tang, Boise, ID (US)

(73) Assignee: MICRON TECHNOLOGY, INC., Boise, ID (US)

(21) Appl. No.: 13/275,582

(22) Filed: Oct. 18, 2011

(51) Int. Cl. H01L 21/308

(52) U.S. Cl. 438/669; 257/E21.585

(57) ABSTRACT

A method of forming circuit structures within openings includes forming pairs of spaced projections that project elevationally relative to a support material on opposing sides of respective openings formed into the support material. At least two of the spaced projections of different of the pairs are received between immediately adjacent of the openings. Conductive metal is formed elevationally over the projections and into and overfilling the openings. The metal is of a composition different from that of at least elevationally outermost portions of the projections. The metal is removed from being elevationally over the projections and at least some of the metal between the projections is removed. Other embodiments and aspects are disclosed.

### TECHNICAL FIELD

Embodiments disclosed herein pertain to methods of forming circuit structures within openings and to methods of forming conductive lines across at least a portion of a substrate.

### BACKGROUND

Elemental metals and metal alloys are commonly used as materials for conductive interconnect lines in the fabrication of integrated circuitry. Further, such materials may be used in other circuit structures, for example as electrode material in capacitors and in memory cells, and in transistor gates.

One manner of forming a conductive metal circuit structures is to form openings into dielectric material that individually have the desired shape of at least a lower portion of a particular circuit structure. The metal is then deposited over the dielectric to a thickness that overfills the openings. The metal is polished back at least to the elevationally outermost surface of the dielectric, whereby desired structures are individually formed within the dielectric, and may be laterally isolated from each other by the dielectric.

The conductive metal can be removed back to the dielectric by one or both of chemical etching and mechanical polishing techniques. Certain conductive metals, for example copper, silver, and aluminum, have a tendency to be pulled out of the openings during the metal removal, particularly where there is a mechanical polishing component to the removal. This is believed to be due to poor adhesion of certain metals to the underlying dielectric and other substrate material.

It has been found that this drawback can be alleviated by first depositing certain conductive adhesion materials and over which the more desirable copper or other metal is then deposited. However, use of adhesion materials requires one or more additional processing steps. For example, such materials must be both deposited and then removed from over the dielectric after removing the more desirable metal. The removal of at least two materials from over the dielectric may require change of processing chemistry and/or conditions to effect the removal. Regardless, the conductive adhesion materials may not have conductivity as high as a desired metal that does not inherently adhere well to certain substrate materials.

Also, some circuit structures may not tolerate or function in the presence of additional adhesion material. For example, certain memory such as Resistive Random Access Memory (RRAM) and Conductive Bridging Random Access Memory (CBRAM) may not tolerate conductive adhesion material between a copper or other metal electrode and the programmable material of such memory cells.

Accordingly, it would be desirable to enable fabrication of circuit structures within dielectric or other material that does not require provision of separate adhesion material. While the invention was motivated in addressing these issues, the invention is not necessarily so limited.

### BRIEF DESCRIPTION OF THE DRAWINGS

FIG. 1 is a diagrammatic sectional view of a substrate in process in accordance with an embodiment of the invention.

FIG. 2 is diagrammatic top view of the substrate of FIG. 1, with FIG. 1 being taken through line 1-1 in FIG. 2.

FIG. 3 is a view of the FIG. 1 substrate at a processing stage subsequent to that shown by FIG. 1.

FIG. 4 is a view of the FIG. 3 substrate at a processing stage subsequent to that shown by FIG. 3.

FIG. 5 is top view of the substrate of FIG. 4, with FIG. 4 being taken through line 4-4 in FIG. 5.

FIG. 6 is a view of the FIG. 4 substrate at a processing stage subsequent to that shown by FIG. 4.

FIG. 7 is top view of the substrate of FIG. 6, with FIG. 6 being taken through line 6-6 in FIG. 7.

FIG. 8 is a view of the FIG. 6 substrate at a processing stage subsequent to that shown by FIG. 6.

FIG. 9 is top view of the substrate of FIG. 8, with FIG. 8 being taken through line 8-8 in FIG. 9.

FIG. 10 is a view of the FIG. 8 substrate at a processing stage subsequent to that shown by FIG. 8.

FIG. 11 is a view of the FIG. 10 substrate at a processing stage subsequent to that shown by FIG. 10.

FIG. 12 is top view of the substrate of FIG. 11, with FIG. 11 being taken through line 11-11 in FIG. 12.

FIG. 13 is a view of the FIG. 11 substrate at a processing stage subsequent to that shown by FIG. 11.

FIG. 14 is top view of the substrate of FIG. 13, with FIG. 13 being taken through line 13-13 in FIG. 14.

FIG. 15 is a diagrammatic sectional view of a substrate in process in accordance with an embodiment of the invention.

FIG. 16 is a diagrammatic sectional view of a substrate in process in accordance with an embodiment of the invention.

FIG. 17 is a diagrammatic sectional view of a substrate in process in accordance with an embodiment of the invention.

FIG. 18 is a diagrammatic sectional view of a substrate in process in accordance with an embodiment of the invention.

FIG. 19 is a view of the FIG. 18 substrate at a processing stage subsequent to that shown by FIG. 18.

FIG. 20 is a diagrammatic sectional view of a substrate in process in accordance with an embodiment of the invention.

FIG. 21 is a diagrammatic sectional view of a substrate in process in accordance with an embodiment of the invention.

FIG. 22 is diagrammatic top view of the substrate of FIG. 21, with FIG. 21 being taken through line 21-21 in FIG. 22.

FIG. 23 is a view of the FIG. 21 substrate at a processing stage subsequent to that shown by FIG. 21.

FIG. 24 is a view of the FIG. 23 substrate at a processing stage subsequent to that shown by FIG. 23.

FIG. 25 is a view of the FIG. 24 substrate at a processing stage subsequent to that shown by FIG. 24.

FIG. 26 is top view of the substrate of FIG. 25, with FIG. 25 being taken through line 25-25 in FIG. 26.

FIG. 27 is a view of the FIG. 25 substrate at a processing stage subsequent to that shown by FIG. 25.

FIG. 28 is top view of the substrate of FIG. 27, with FIG. 27 being taken through line 27-27 in FIG. 28.

FIG. 29 is a view of the FIG. 27 substrate at a processing stage subsequent to that shown by FIG. 27.

FIG. 30 is a diagrammatic sectional view of a substrate in process in accordance with an embodiment of the invention.

FIG. 31 is a diagrammatic sectional view of a substrate in process in accordance with an embodiment of the invention.

FIG. 32 is a view of the FIG. 31 substrate at a processing stage subsequent to that shown by FIG. 31.

FIG. 33 is a diagrammatic sectional view of a substrate in process in accordance with an embodiment of the invention.

### DETAILED DESCRIPTION OF EXAMPLE EMBODIMENTS

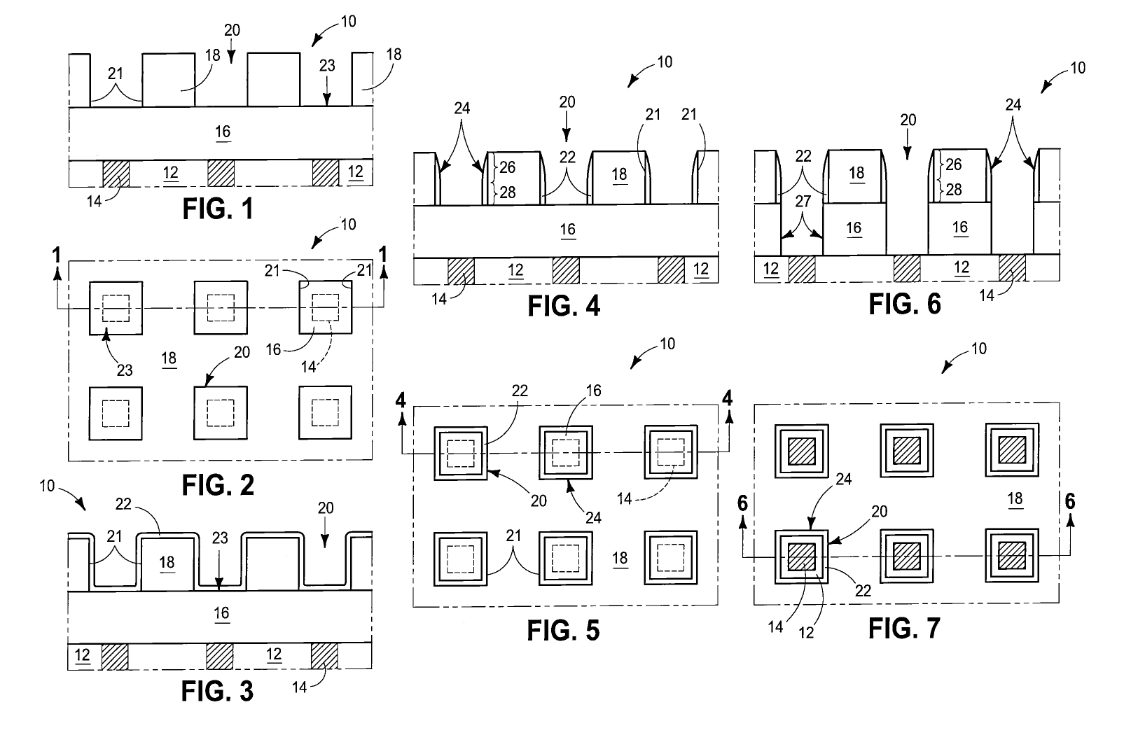

Example embodiments of methods of forming circuit structures within openings in accordance with the invention are initially described with reference to FIGS. 1-14 with respect to a substrate construction 10. Referring to FIGS. 1 and 2, an elevationally outer portion of a substrate construction 10 includes dielectric material 12 having conductive structures 14 extending upwardly to an elevationally outermost surface of dielectric material 12. Other material and structure (not shown) of integrated circuit components may be below dielectric material 12 and to which conductive structures 14 may connect.

Support material 16 has been provided elevationally outward of substrate 12/14. Such may be homogenous or non-homogenous; may be any of dielectric, conductive, and/or semi-conductive; and may be sacrificial. In one embodiment, support material 16 is dielectric, and wholly or partially remains in the finished integrated circuit construction. Examples include doped or undoped silicon dioxide, and silicon nitride. Openings will ultimately be formed into support material 16 and into which at least conductive metal will be deposited and from which circuit structures will be fabricated. Material 16 will at least initially support such conductive metal during deposition, and is this characterized for convenience as “support material”.

Masking material 18 has been formed elevationally outward of support material 16. Material 18 may be homogenous or non-homogenous, with photoresist and/or hard-masking materials being examples. Openings 20 have been formed in masking material 18, and in one embodiment extend there-through to support material 16. Example individual openings 20 are shown to be quadrilateral in shape, although any shaped opening may be used, for example such as trenches that are horizontally elongated across some or most of the substrate. The example embodiments of FIGS. 1-14 show individual of openings 20 overlying a single conductive structure 14 formed within dielectric material 12. Other configurations overlying multiple or none of conductive structures 14 may be used. Regardless, individual openings 20 have opposing sidewalls 21 (i.e., in at least one straight-line cross section) and a base 23.

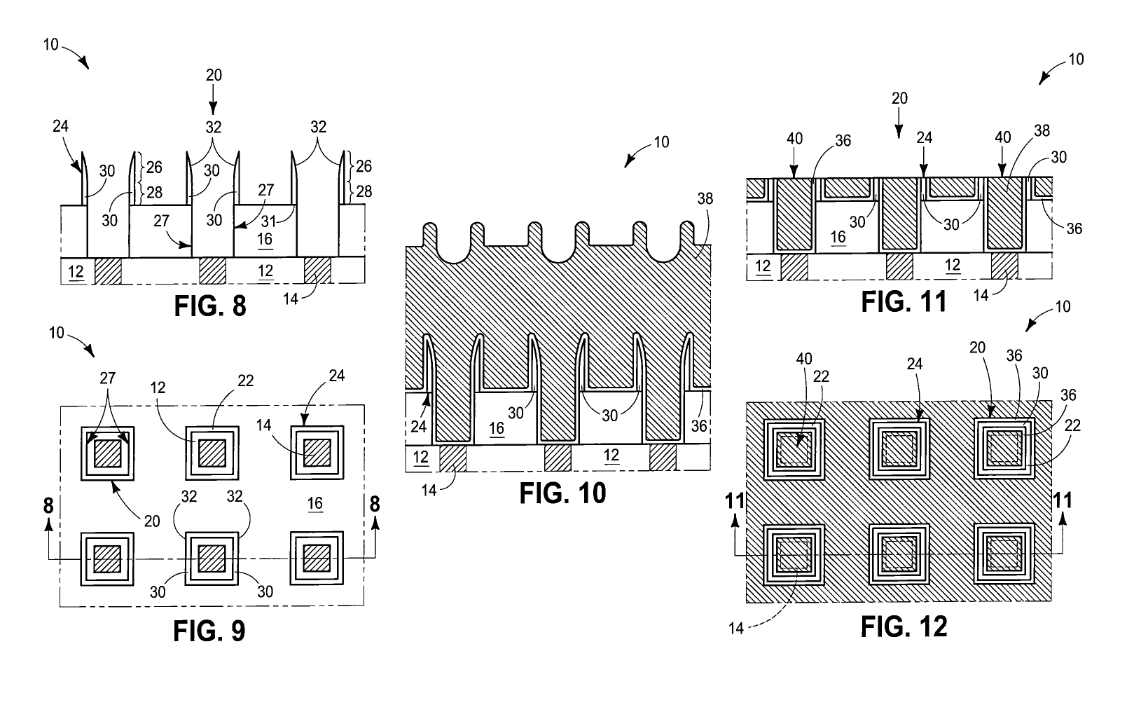

In one embodiment, a lining is formed laterally over the opposing sidewalls of the openings in the masking material. The lining may be formed by any method, with an example method being shown in FIGS. 3-5. Referring to FIG. 3, a material 22 has been deposited elevationally over masking material 18, and laterally over sidewalls 21 and elevationally over bases 23 of openings 20. Material 22 may be homogenous or non-homogenous; may be any of conductive, semi-conductive, and/or dielectric; and may be wholly sacrificial. Further, such may be of the same or different composition from that of support material 16. In one ideal embodiment, at least the outermost portion of material 22 is of different composition from that of support material 16 to facilitate selective etching of material 16 relative to material 22. Example materials 22 include conductive or dielectric oxides, conductive or dielectric nitrides, conductive silicides, other dielectric or conductive metal compounds, and organic material, and regardless of method of deposition. One example deposition thickness range for material 22 is from about 20 Angstroms to about 100 Angstroms. For convenience and distinguishing clarity in some of the claims, material 22 is hereafter referred to as “projection material” as such is ultimately formed to have at least some elevationally projecting characteristic.

Referring to FIGS. 4 and 5, projection material 22 has been anisotropically etched from being received elevationally over masking material 18 and from being over opening bases 23 (i.e., from over center portions of bases 23). The depicted etching as been conducted in such a manner to leave at least some of projection material 22 laterally over opening sidewalls 21 to form an individual lining 24 within individual openings 20. Linings 24 may be considered individually as having an elevationally outermost portion 26 and an elevationally innermost portion 28. In one embodiment, outermost portion 26 is laterally narrower than innermost portion 28 (i.e., portion 26 has an average lateral width which is narrower if the outermost and/or innermost portion is not of constant lateral width). Portions 26 and 28 may be arbitrarily chosen as a function of elevational thickness of lining 24, and need not be of the same elevational thickness above support material 16.

Referring to FIGS. 6 and 7, masking material 18 and lining 24 have been used as a mask while removing support material 16 to extend openings 20 into support material 16. In one embodiment and as shown, openings 20 are extended to outermost surfaces of conductive structures 14. An example technique for extending openings 20 includes anisotropic etching which in one embodiment is conducted selectively relative to materials 12, 14, 18, and 26/22. In the context of this document, a selective etch requires removal of the one material relative to the stated another material(s) at a removal rate of at least 2:1. Extended openings 20 have opposing sides 27 within support material 16 (i.e., in at least one straight-line cross section).

Referring to FIGS. 8 and 9, masking material 18 (not shown) has been removed to leave individual linings 24 projecting elevationally outward relative to the respective extended openings 20 in support material 16. An example removing technique is anisotropic etching of material 18 which in one embodiment is conducted selectively relative to materials 12, 14, 16 and 26/22.

In one embodiment, FIGS. 8 and 9 depict formation of pairs 32 of spaced projections 30 (i.e., in at least one straight-line cross section) that project elevationally relative to support material 16 on opposing sides 27 of respective openings 20 formed into support material 16. The processing embodiment of FIGS. 1-7 is but only one example of forming spaced projections 30, and alternately or additionally spaced projections 30 may be formed by any existing or yet-to-be-developed techniques. For example, spaced projections may be formed by a technique whereby a material 22 is not formed laterally against a sidewall of the same or another material, or not necessarily formed within an opening. Spaced projections may be connected at their horizontal ends (FIG. 9) or may not be so connected (not shown). Regardless, in one embodiment, at least two of spaced projections 30 of different pairs 32 are received between immediately adjacent openings 20.

In one embodiment, spaced projections 30 on opposing sides 27 of a single opening 20 have respective elevationally outermost portions 26 that are laterally narrower than the respective innermost portions 28, and regardless of whether there are at least two spaced projections of different of the pairs received between immediately adjacent openings 20. Other attributes as described above with respect to material 22 and lining 24 may be used in fabrication of spaced projections 30.

Circuit structures comprising conductive metal will ultimately be formed within the respective openings 20. In one embodiment, one example circuit structure comprises a pair of electrodes having intervening material there-between. One of the electrodes may comprise a node location (e.g., the outermost surface of a conductive structure 14) on substrate 10 to which an opening 20 in support material 16 extends. For example, one example circuit structure comprises a capacitor wherein the intervening material would be a capacitor dielectric. Another example includes a programmable memory cell (e.g., RRAM or CBRAM) wherein the intervening material comprises programmable material. Regardless, FIG. 10 depicts an example embodiment wherein an intervening material 36 has been deposited over projections 30 or linings 24 and into openings 20 to line openings 20. Intervening material 36 may be homogenous or non-homogenous, and may be dielectric, semiconductive, conductive, and/or programmable depending upon the circuit structure being fabricated. Conductive metal 38 is ultimately formed elevationally over projections 30 or linings 24 and into and over-filling the respective openings 20. Metal 38 is also inherently formed over intervening material 36 where such is used. Metal 38 may be homogenous or non-homogenous, and regardless is of a composition different from that of at least elevationally outermost portions 26 (FIG. 8) of projections 30 or linings 24. In one embodiment, metal 38 predominantly comprises copper, aluminum, and/or silver in elemental or alloy forms.

Referring to FIGS. 11 and 12, metal 38 has been removed from being elevationally over linings 24 and projections 30, and at least some of metal 38 has been removed from between linings 24 and projections 30. In one embodiment, such removing is by polishing (i.e., having at least some mechanical component) and in one embodiment by chemical mechanical polishing. Regarding problems or issues identified in the Background section, chemical mechanical polishing inwardly to a point of outwardly exposing projections 30 and linings 24 above support material 16 may eliminate or at least reduce tendency of the polishing action to pull conductive metal 28 out from openings 20. Accordingly, in one embodiment, no outer conductive adhesion layer in addition to or as a part of conductive metal 38 may be necessary or used.

Removal of metal 38 may be conducted elevationally inward to the point of just outwardly exposing (not shown) projections 30 and linings 24, or may be continued at least partially elevationally inward (as shown). Regardless, circuit structures 40 are formed within individual openings 20.

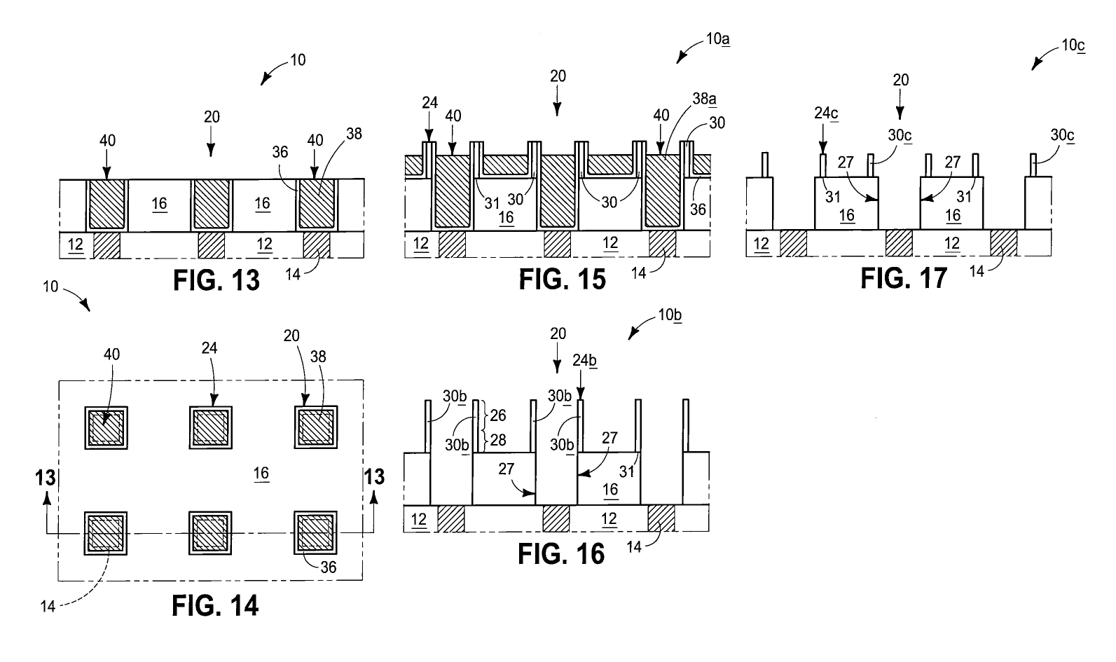

In one embodiment, projections 30 and linings 24 are removed from the substrate after removing metal 38 from being elevationally over projections 30 and linings 24. In one embodiment, all metal 38 is removed from being elevationally outward of support material 16 after removing metal 38 from being elevationally over projections 30 and linings 24. FIGS. 13 and 14, by way of example only, depict processing whereby both occur, for example by removing materials 30 (not shown), 38, and 36 elevationally inward at least to the elevationally outermost surfaces of support material 16. One or more of materials 30, 38 and/or 36 may be removed by chemical etching and/or by polishing (i.e., having at least some mechanical component). Regardless, support material may be wholly or partially sacrificial, and might or might not remain as part of the finished circuitry construction.

In one embodiment, removal of metal 38 may be conducted using chemical etching in the absence of polishing, and in one example may be conducted selectively relative to projections 30 or linings 24. For example, FIG. 15 depicts an alternate embodiment substrate construction 10a showing alternate processing to that depicted by FIG. 11. Like numerals from the above-described embodiments have been used where appropriate, with some construction differences being indicated with the suffix “a”. In FIG. 15, metal 38a has been etched back by chemical etching conducted selectively relative to projections 30, linings 24, and material 36 to form the circuit structures 40 within the respective openings 20. Such example chemical etching may be stopped, for example, based on time and may be continued inwardly beyond that shown in FIG. 15.

FIG. 8 depicts an example embodiment wherein projections 30 and linings 24 have respective elevationally outermost portions 26 that are laterally narrower (i.e., at least on average) than their respective inner portions 28. Nevertheless, embodiments of the invention include forming the spaced projections to be of uniform lateral width, for example as shown with respect to a substrate construction 10b shown in FIG. 16. Like numerals from the above-described embodiments have been used where appropriate, with some construction differences being indicated with the suffix “b”. FIG. 16 shows alternate processing to that shown by FIG. 8 wherein spaced projections 30b and linings 24b are formed to be of uniform lateral width. Alternately as another example, the respective elevationally outermost portions 26 may be laterally wider than the respective innermost portions 28 (not shown).

Projections 30/30b and linings 24/24b may be considered as comprising respective bases 31 (FIGS. 8, 15, 16). The structures of FIGS. 8-16 show the projections and linings being formed to have a side of their respective bases 31 laterally align with elevationally outermost portions of their respective opposing side 27 of openings 20 within support material 16. Alternately as an example, the projections may be formed to have their respective bases 31 everywhere spaced laterally outward from elevationally outermost portions of their respective opposing side of the opening, for example as shown with respect to a substrate construction 10c in FIG. 17. Like numerals from the above embodiments have been used where appropriate, with some construction differences being indicated with the suffix “c”. Projections 30c and linings 24c have bases 31 everywhere spaced laterally outward from elevationally outermost portions of their respective opposing side 27 of a respective opening 20. Other attributes as described above may be used. In one embodiment, spaced projections 30 on opposing sides 27 of a single opening 20 have respective bases that are everywhere spaced laterally outward from elevationally outermost portions of the opposing sides of the opening regardless of whether there are at least two spaced projections of different of the pairs received between immediately adjacent openings 20.

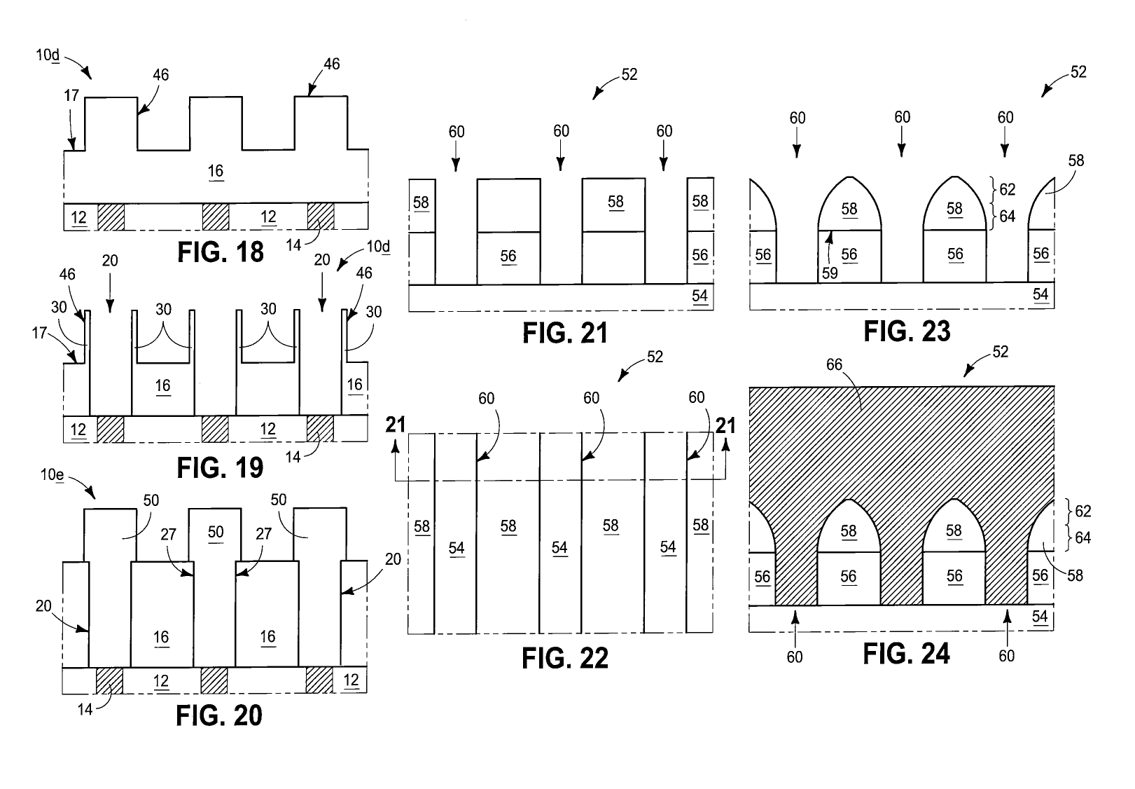

Alternate example methods of forming projections and openings in conjunction with any of the above-described embodiments are next described with respect to a substrate construction 10d in FIGS. 18 and 19. Like numerals from the above-described embodiments have been used where appropriate, with some construction differences being indicated with the suffix “d” or with different numerals. Referring to FIG. 18, spaced projecting masses 46 have been formed to project elevationally outward relative to an elevationally outermost surface 17 of support material 16. Masses 46 may be homogenous or non-homogenous, and may comprise the same or different composition from that of material 16. Further by way of example, elevationally outermost surface 17 may or may not be planar. The construction of FIG. 16 may be formed, by way of example, by providing a suitably thick layer of support material 16 followed by patterning and subtractive etch thereof to produce the FIG. 18 construction.

Referring to FIG. 19, individual openings 20 have been etched through projecting masses 46 and into support material 16. The etching leaves material of masses 46 adjacent openings 20, with spaced projections 30 comprising material of masses 46. An example technique for forming openings 20 and correspondingly projections 30 comprises photolithographic patterning and subtractive anisotropic etch.

Yet another example embodiment of producing the structure of FIG. 19 is described with respect to a substrate construction 10e in FIG. 20. Like numerals from the above-described embodiments have been used where appropriate, with some construction differences being indicated with the suffix “e” or with different numerals. FIG. 20 depicts a different starting construction from that of FIG. 18 wherein openings 20 have already been formed within support material 16. Thereafter, material (e.g., support material 16) that is laterally spaced from opposing sides 27 of openings 20 may be removed to leave material (e.g., support material 16) adjacent openings 20 that becomes material of the spaced projections 30. By way of example only, FIG. 20 depicts suitable masking material 50 having been patterned to overlie laterally outward beyond the respective openings 20 in support material 16. Subsequent timed anisotropic etching of support material 16 selectively relative to masking material 50 may be conducted to etch the exposed support material 16 elevationally inward, for example to a degree as shown in FIG. 19. The masking material may thereafter be removed (not shown) to produce the same essential construction as shown in FIG. 19.

By way of an additional example, the above-described processing may be used to form circuit structures in the form of conductive lines which extend longitudinally across at least a portion of the substrate. Such may result when forming the openings in the support material in the form of individual trenches which extend longitudinally across some portion of the substrate. The above generally described methodology may also be used in fabricating any other existing or yet-to-be-developed circuit structures. Further, not all circuit structures being fabricated in accordance with embodiments of the invention need be of the same construction. Regardless, example embodiments in accordance with the invention include methods of forming conductive lines (e.g. local or global interconnect lines, gate lines, etc.) across at least a portion of a substrate, and are next described with reference to FIG. 21-29 with respect to a substrate construction 52.

Referring to FIGS. 21 and 22, substrate construction 52 comprises a substrate 54 having support material 56 and projection material 58 formed thereover. Substrate 54 in the depicted cross section may be homogenous or non-homogenous, for example comprising multiple different composition regions, materials, and/or layers which are not particularly material to embodiments of the invention. Support material 56 may have any of the same attributes described above with respect to support material 16, and projection material 58 may have any of the attributes described above with respect to projection material 22. Regardless, trenches 60 have been formed through projection material 58 and into support material 56. In one embodiment and as shown, trenches 60 have been formed through support material 56 to substrate 54.

Referring to FIG. 23, elevationally outermost portions 62 of projection material 58 have been laterally narrowed between trenches 60 compared to elevationally innermost portions 64 of projection material 58 between trenches 60 (i.e., a portion 62 has an average lateral width which is narrower than a respective portion 64 if the outermost and/or innermost portion is not of constant lateral width). Portions 62 and 64 may be arbitrarily chosen as a function of elevational thickness of projection material 58, and need not be of the same elevational thickness above support material 56. An example technique for forming laterally narrowed projection material 58 includes facet etching thereof. As a specific example where projection material comprises any of polysilicon, titanium nitride, tantalum nitride, or tungsten, an example facet etching technique includes using a capacitively coupled reactor with example parameters of pressure from about 80 mTorr to about 120 mTorr, substrate temperature from about 30° C. to about 60° C., source power from about 800 watts to about 2,000 watts, and bias voltage at from about 300 volts to about 800 volts. An example etching gas is Ar at from about 20 sccm to about 100 sccm without or with O₂ at from about 5 sccm to about 20 sccm. Regardless, in one embodiment and as shown, projection material 30 has respective bases 59 that laterally align with elevationally outermost portions of opposing sides of openings 60 within support material 56.

The processing of FIGS. 21-23 depicts but another example embodiment of forming spaced projections that project elevationally from support material on opposing sides of an opening formed into the support material. Such projections have respective elevationally outermost portions that are laterally narrower than their respective innermost portions.

Referring to FIG. 24, conductive metal 66 has been formed elevationally over projection material 58 into and over-filling trenches 60. Metal 66 is of a composition different from that of at least the narrowed elevationally outermost portion 62 of projection material 58. Conductive metal 66 may have any of the attributes described above with respect to conductive metal 38. Further, a liner, non-metallic material, and/or other construction (not shown) might be deposited or formed into trenches 60 prior to forming conductive metal 66.

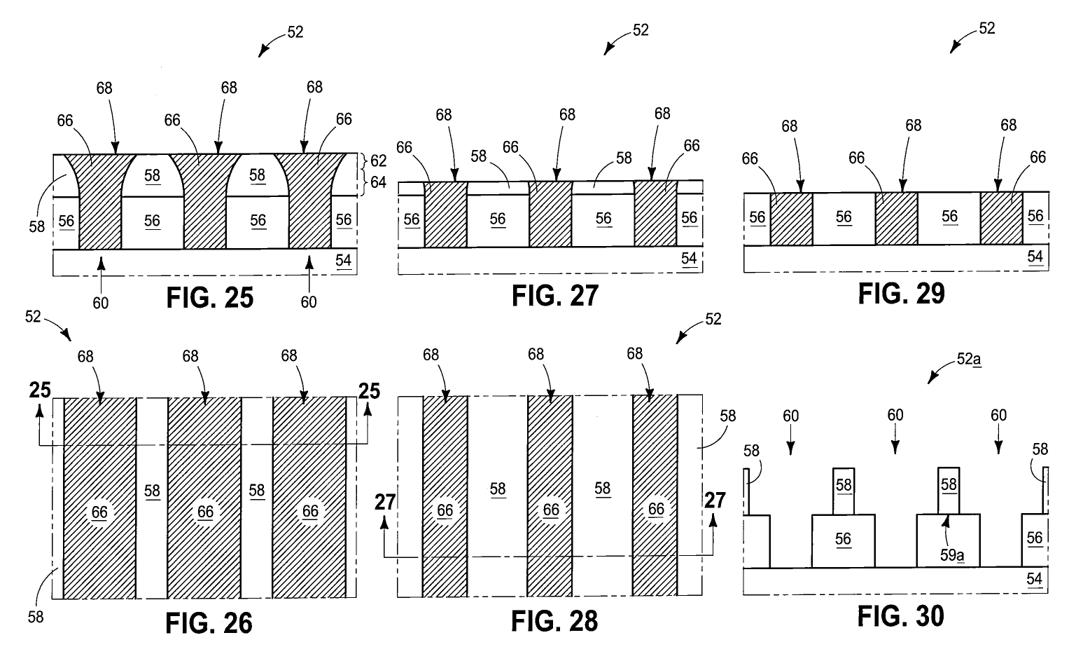

Referring to FIGS. 25 and 26 metal 66 has been removed from being elevationally over tops of elevationally outermost portions 62 of projection material 58, and at least some of metal 66 has been removed from between projection material 58. Removal of metal 66 may be conducted elevationally inward to the point of just outwardly exposing (not shown) projection material 58, or may be continued at least partially elevationally inward (as shown). Regardless, conductive lines 68 are thus formed within individual trenches 60 and which extend at least across a portion of the substrate. The removing of metal 66 may occur by any of the removing techniques described above with respect to removing metal 38.

Removing action may continue inwardly, for example as shown in FIGS. 27 and 28 wherein some of projection material 58 remains over support material 56. As an additional example, removing of metal material 66 and projection material 58 may be continued inwardly whereby all of the projection material 58 is removed from being over support material 56, for example as shown in FIG. 29.

The processing of FIGS. 21-23 provides projection material 30 to have respective bases 59 having a side that laterally aligns with elevationally outermost portions of opposing sides of openings 60 within support material 56. Example alternate processing to that shown by FIG. 23 is shown in FIG. 30 with respect to a substrate construction 52a. Like numerals from the FIGS. 21-29 embodiments have been used where appropriate, with some construction differences being indicated with the suffix “a”. In FIG. 30, projection material 58 has been processed whereby bases 59a are everywhere spaced laterally outward from elevationally outermost portions of the opposing sides of openings 60 within support material 56. By way of example, such may result from an isotropic etch which removes material approximately equally from the sides and tops of projection material 58. Alternately, chemistries and conditions may be used which tend to etch greater material from the lateral sides of projection material 58 than from the respective tops. Alternately, chemistries and conditions may be used which tend to etch greater material from the tops than from the lateral sides. Regardless, etching or other removal may be conducted which is selective to remove material 58 relative to support material 56. Support material 56 may include an elevationally outermost portion which is of different composition than an elevationally innermost portion (not shown) in this and/or earlier-described embodiments.

An example substantially isotropic etch of projection material 58 can result by plasma etching of the FIG. 21 substrate within an inductively coupled reactor. Example etching parameters which will achieve essentially isotropic etching where projection material 58 is an organic-comprising material are pressure from about 2 mTorr to about 50 mTorr, substrate temperature from about 0° C. to about 100° C., source power from about 150 watts to about 500 watts, and bias voltage at less than or equal to about 25 volts. An example etching gas is a combination of Cl₂ from about 20 sccm to about 100 sccm and O₂ from about 10 sccm to about 50 sccm. While such an example etch is essentially isotropic, greater lateral etching of spaced projection material 58 will occur as two sides are laterally exposed as compared to only a single top surface thereof.

If even more lateral etching is desired in comparison to vertical etching, example parameter ranges in an inductively coupled reactor include pressure from about 2 mTorr to about 20 mTorr, source power from about 150 watts to about 500 watts, bias voltage at less than or equal to about 25 volts, substrate temperature of from about 0° C. to about 110° C., Cl₂ and/or HBr flow from about 20 sccm to about 100 sccm, O₂ flow from about 5 sccm to about 20 sccm, and CF₄ flow from about 80 sccm to about 120 sccm.

It may be desired that greater removal occur from the tops of spaced projection material 58 than from the sides, for example to either achieve equal elevation and width reduction or more elevation than width reduction. The example parameters for achieving greater etch rate in the vertical direction as opposed to the lateral direction includes pressure from about 2 mTorr to about 20 mTorr, temperature from about 0° C. to about 100° C., source power from about 150 watts to about 300 watts, bias voltage at greater than or equal to about 200 volts, Cl₂ and/or HBr flow from about 200 sccm to about 100 sccm, and O₂ flow from about 10 sccm to about 20 sccm.

Alternate and/or additional removal techniques may be used.

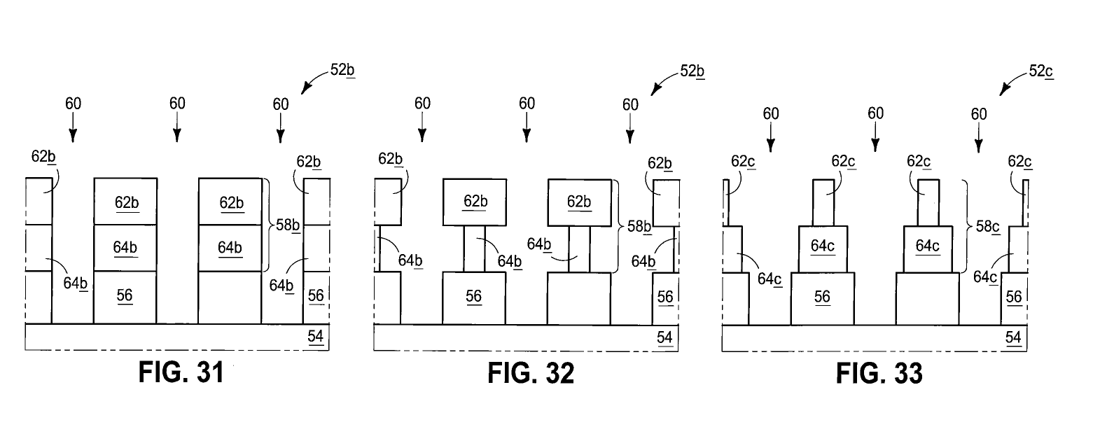

Another example embodiment is described with reference to FIGS. 31 and 32 with respect to a substrate construction 52b. Like numerals from the FIG. 30 embodiment have been used where appropriate, with some construction differences being indicated with the suffix “b”. Referring to FIG. 31, projection material 58b comprises elevationally outermost portions 62b and elevationally innermost portions 64b. In one embodiment, an outermost portion 62b and an innermost portion 64b are of different composition relative one another (e.g., one can be etched laterally at a faster rate than the other and/or selectively relative to the other as “selective” is defined above in this document).

Referring to FIG. 32, elevationally innermost portions 64b have been laterally narrowed compared to elevationally outermost portions 62b. In one embodiment, such may occur by laterally etching innermost portion 64b at a faster rate than any lateral etching of outermost portion 62b (e.g., by a selective etch). FIG. 32 shows an embodiment where essentially no lateral etching has occurred of outermost portion 62b, although an embodiment of the invention also contemplates some lateral etching of outermost portion 62b (not shown). Alternate and/or additional removal techniques may be used. Regardless, spaced projections have been formed wherein respective outermost portions 62b are laterally wider than respective innermost portions 64b.

Another example embodiment is described with reference to FIG. 33 with respect to a substrate construction 52c. Like numerals from the FIGS. 30-33 embodiments have been used where appropriate, with some construction differences being indicated with the suffix “c”. In FIG. 33, orientation and/or composition of portions 62c and 64c have been reversed in comparison to the FIGS. 31 and 32 embodiment, and some lateral etching of portion 64c has occurred. Alternately by way of example, there may be no lateral etching of portion 64c (not shown).

With respect to all embodiments, additional processing might be conducted elevationally and/or laterally outward of that shown in the Figures, for example to further reduce tendency of metal to be removed from openings during removal action such as polishing. As an example, additional material may be formed that has openings therein into which the metal is deposited. These filled openings may extend longitudinally over the substrate, for example from array circuitry area to peripheral circuitry area (micro-scale). Additionally or alternately, the filled openings may extend longitudinally across or along at least a majority of individual wafer die sites and/or across or along multiple die sites (macro-scale). Regardless, the additional material and metal-filled openings may be entirely sacrificial, for example when such are formed elevationally outward of the example circuitry shown in the Figures.

### CONCLUSION

In some embodiments, methods of forming circuit structures within openings comprise providing support material over a substrate. Pairs of spaced projections that project elevationally relative to the support material are formed on opposing sides of respective openings formed into the support material. At least two of the spaced projections of different of the pairs are received between immediately adjacent of the openings. Conductive metal is formed elevationally over the projections and into and overfilling the openings. The metal is of a composition different from that of at least elevationally outermost portions of the projections. The metal is removed from being elevationally over the projections and at least some of the metal between the projections is removed.

In some embodiments, methods of forming a circuit structure within an opening comprise providing support material over a substrate. Spaced projections that project elevationally relative to the support material are formed on opposing sides of an opening formed into the support material. The projections have respective elevationally outermost portions and elevationally innermost portions. The respective outermost portions are laterally narrower than the respective innermost portions. Conductive metal is formed elevationally over the projections and into and overfilling the opening. The metal is of a composition different from that of at least the elevationally outermost portions of the projections. The metal is removed from being elevationally over the projections and at least some of the metal between the projections is removed.

In some embodiments, methods of forming a circuit structure within an opening comprising providing support material over a substrate. Spaced projections that project elevationally relative to the support material are formed on opposing sides of an opening formed into the support material. The projections have respective bases that are everywhere spaced laterally outward from elevationally outermost portions of the opposing sides of the opening. Conductive metal is formed elevationally over the projections and into and overfilling the opening. The metal is of a composition different from that of at least elevationally outermost portions of the projections. The metal is removed from being elevationally over the projections and removing at least some of the metal between the projections.

In some embodiments, methods of forming a circuit structure within an opening comprise forming an opening in masking material that is elevationally outward of support material of a substrate. A lining is formed laterally over opposing sidewalls of the opening in the masking material. The masking material and lining are used as a mask while removing support material to extend the opening into the support material. The masking material is removed to leave the lining projecting elevationally outward relative to the extended opening in the support material. Conductive metal is formed elevationally over the lining and into and overfilling the extended opening in the support material. The metal is of a composition different from that of at least elevationally outermost portions of the lining. The metal is removed from being elevationally over the lining and at least some of the metal between the lining is removed.

In some embodiments, methods of forming conductive lines across at least a portion of a substrate comprise providing support material over a substrate and projection material over the support material. Trenches are formed through the projection material and into the support material. Elevationally outermost portions of the projection material between the trenches are laterally narrowed compared to elevationally innermost portions of the projection material between the trenches. Conductive metal is formed elevationally over the projection material into and overfilling the trenches. The metal is of a composition different from that of at least the narrowed elevationally outermost portions of the projection material. The metal is removed from being elevationally over tops of the elevationally outermost portions of the projection material and at least some of the metal between the projection material is removed.

In some embodiments, methods of forming a circuit structure within an opening comprise providing support material over a substrate. Spaced projections that project elevationally relative to the support material are formed on opposing sides of an opening formed into the support material. The projections have respective elevationally outermost portions and elevationally innermost portions. The respective outermost portions are laterally wider than the respective innermost portions. Conductive metal is formed elevationally over the projections and into and overfilling the opening. The metal is of a composition different from that of at least the elevationally outermost portions of the projections. The metal is removed from being elevationally over the projections and at least some of the metal is removed between the projections.

In some embodiments, methods of forming conductive lines across at least a portion of a substrate comprise providing support material over a substrate and projection material over the support material. Trenches are formed through the projection material and into the support material. Elevationally innermost portions of the projection material between the trenches are laterally narrowed compared to elevationally outermost portions of the projection material between the trenches. Conductive metal is formed elevationally over the projection material into and overfilling the trenches. The metal is of a composition different from that of at least the narrowed elevationally outermost portions of the projection material. The metal is removed from being elevationally over tops of the elevationally outermost portions of the projection material and at least some of the metal between the projection material is removed.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of forming circuit structures within openings, comprising:
providing support material over a substrate;
forming pairs of spaced projections that project elevationally relative to the support material on opposing sides of respective openings formed into the support material, at least two of the spaced projections of different of the pairs being received between immediately adjacent of the openings;
forming conductive metal elevationally over the projections and into and overfilling the openings, the metal being of a composition different from that of at least elevationally outermost portions of the projections; and
removing the metal from being elevationally over the projections and removing at least some of the metal between the projections.

2. The method of claim 1 comprising removing the projections from the substrate after removing the metal from being elevationally over the projections.

3. The method of claim 1 comprising removing all of the metal from being elevationally outward of the support material after removing the metal from being elevationally over the projections.

4. The method of claim 1 wherein the removing comprises polishing.

5. The method of claim 4 wherein the removing comprises chemical mechanical polishing.

6. The method of claim 1 wherein the removing comprises chemical etching in the absence of polishing.

7. The method of claim 6 wherein the etching is conducted selectively relative to the projections.

8. The method of claim 1 wherein the projections have respective elevationally outermost portions and elevationally innermost portions, the respective outermost portions being laterally narrower than the respective innermost portions.

9. The method of claim 1 comprising forming the spaced projections to be of uniform lateral width.

10. The method of claim 1 wherein forming the projections and openings comprises:
forming spaced projecting masses that project elevationally outward relative to an elevationally outermost surface of the support material;
etching individual of the openings through the projecting masses and into the support material, the etching leaving material of the masses adjacent the openings, the spaced projections comprising said material of the masses.

11. The method of claim 1 wherein forming the projections and openings comprises:
etching the openings into the support material;
after the etching, removing material that is laterally spaced from opposing sides of the openings; the etching leaving material adjacent the openings that comprises material of the spaced projections.

12. The method of claim 1,
wherein the circuit structures are respectively formed to comprise a pair of electrodes having intervening material there-between, one of the electrodes comprising a node location on the substrate to which the opening in the support material extends, and comprising:
depositing the intervening material over the projections and into the openings to line the openings, the metal being formed over the intervening material into and overfilling the openings.

13. The method of claim 12 wherein the circuit structures comprise respective memory cells, and the intervening material comprises programmable material.

14. The method of claim 1 wherein the projections are conductive.

15. The method of claim 1 wherein the projections are dielectric.

16. The method of claim 1 wherein the projections comprise at least one of a dielectric oxide, dielectric nitride, conductive elemental-form metal, and a conductive metal compound.

17. The method of claim 1 wherein forming the spaced projections comprises anisotropic etching of projection material received elevationally over masking material and elevationally over a base of an opening in the masking material.

18. The method of claim 1 comprising forming the projections to have respective bases having a side that laterally aligns with elevationally outermost portions of their respective opposing side of the respective openings.

19. The method of claim 1 comprising forming the projections to have respective bases that are everywhere spaced laterally outward from elevationally outermost portions of their respective opposing side of the respective openings.

20. A method of forming a circuit structure within an opening, comprising:
providing support material over a substrate;
forming spaced projections that project elevationally relative to the support material on opposing sides of an opening formed into the support material, the projections having respective elevationally outermost portions and elevationally innermost portions, the respective outermost portions being laterally narrower than the respective innermost portions;
forming conductive metal elevationally over the projections and into and overfilling the opening, the metal being of a composition different from that of at least the elevationally outermost portions of the projections; and
removing the metal from being elevationally over the projections and removing at least some of the metal between the projections.

21-28. (canceled)

29. A method of forming a circuit structure within an opening, comprising:
providing support material over a substrate;
forming spaced projections that project elevationally relative to the support material on opposing sides of an opening formed into the support material, the projections having respective bases that are everywhere spaced laterally outward from elevationally outermost portions of the opposing sides of the opening;
forming conductive metal elevationally over the projections and into and overfilling the opening, the metal being of a composition different from that of at least elevationally outermost portions of the projections; and
removing the metal from being elevationally over the projections and removing at least some of the metal between the projections.

30. A method of forming a circuit structure within an opening, comprising:
forming an opening in masking material that is elevationally outward of support material of a substrate;
forming a lining laterally over opposing sidewalls of the opening in the masking material;
using the masking material and lining as a mask while removing support material to extend the opening into the support material;
removing the masking material to leave the lining projecting elevationally outward relative to the extended opening in the support material;
forming conductive metal elevationally over the lining and into and overfilling the extended opening in the support material, the metal being of a composition different from that of at least elevationally outermost portions of the lining; and
removing the metal from being elevationally over the lining and removing at least some of the metal between the lining.

31-33. (canceled)

34. A method of forming conductive lines across at least a portion of a substrate, comprising:
providing support material over a substrate and projection material over the support material;
forming trenches through the projection material and into the support material;
laterally narrowing elevationally outermost portions of the projection material between the trenches compared to elevationally innermost portions of the projection material between the trenches;
forming conductive metal elevationally over the projection material into and overfilling the trenches, the metal being of a composition different from that of at least the narrowed elevationally outermost portions of the projection material; and
removing the metal from being elevationally over tops of the elevationally outermost portions of the projection material and removing at least some of the metal between the projection material.

35. (canceled)

36. A method of forming a circuit structure within an opening, comprising:
providing support material over a substrate;
forming spaced projections that project elevationally relative to the support material on opposing sides of an opening formed into the support material, the projections having respective elevationally outermost portions and elevationally innermost portions, the respective outermost portions being laterally wider than the respective innermost portions;
forming conductive metal elevationally over the projections and into and overfilling the opening, the metal being of a composition different from that of at least the elevationally outermost portions of the projections; and
removing the metal from being elevationally over the projections and removing at least some of the metal between the projections.

37-38. (canceled)

39. A method of forming conductive lines across at least a portion of a substrate, comprising:
providing support material over a substrate and projection material over the support material;
forming trenches through the projection material and into the support material;
laterally narrowing elevationally innermost portions of the projection material between the trenches compared to elevationally outermost portions of the projection material between the trenches;
forming conductive metal elevationally over the projection material into and overfilling the trenches, the metal being of a composition different from that of at least the narrowed elevationally outermost portions of the projection material; and
removing the metal from being elevationally over tops of the elevationally outermost portions of the projection material and removing at least some of the metal between the projection material.

40-41. (canceled)
